(19) United States
(12) Patent Application Publication
(10) Pub. No.: US 2006/0284998 A1
(43) Pub. Date: Dec. 21, 2006

(54) IMAGE PIXEL OF CMOS IMAGE SENSOR

(76) Inventors: Deuk Hee PARK, Seoul (KR); Won Tae CHOI, Yongin (KR); Shin Jae KANG, Gunpo (KR); Joo Yul Ko, Seongnam (KR)

Correspondence Address: STANZIONE & KIM, LLP, 919 18TH STREET, N.W., SUITE 440, WASHINGTON, DC, 20006, US

(21) Appl. No.: 11/379,419

(22) Filed: Apr. 20, 2006

(30) Foreign Application Priority Data
Jun. 20, 2005 (KR) 2005-0052849

(51) Int. Cl. H04N 5/335

(52) U.S. Cl. 348/308

(57) ABSTRACT

An image pixel of a CMOS image sensor in which a dark diode serving as a dark current source is directly connected to a photo diode so that a dark current generated in an image pixel can be minimized. Further, since noise which can be generated by the dark current can be reduced, a high S/N ratio is obtained, and dynamic range and low illumination characteristics are enhanced. In addition, operational characteristics at high temperature can be improved. The image pixel of a CMOS image sensor includes a photoelectric conversion element that is connected to a first node and ground terminal so as to generate a signal by using incident light, an electric current source that is connected to the first node and a power supply terminal so as to supply a dark current, a first switch that is connected to a second node, the power supply terminal, and the first node and that changes the potential of a node connected to the first node by using the signal charges accumulated in the first node so that the bias of the second node is changed, a second switch that is connected to the first switch and that receives a row selection signal so as to output a potential difference generated by the signal generated by the photoelectric conversion element to a column selection line, and a third switch that is connected between the first node and the power supply terminal and that receives a reset signal so as to reset the signal charges accumulated in the first node.

### CROSS-REFERENCE TO RELATED APPLICATIONS

The application claims the benefit of Korea Patent Application No. 2005-0052849 filed with the Korea Industrial Property Office on Jun. 20, 2005, the disclosure of which is incorporated herein in its entirety by reference.

### BACKGROUND OF THE INVENTION

1. Field of the Invention

The present invention relates to an image pixel of a CMOS image sensor, and more specifically, to an image sensor of a CMOS image sensor, in which a dark diode serving as a dark current source is directly connected to a photo diode so that a dark current generated in an image pixel can be minimized. Further, since noise which can be generated by the dark current can be reduced, a high S/N ratio is obtained, and dynamic range and low illumination characteristics are enhanced. In addition, since characteristic deterioration at high temperature is prevented, operational characteristics at high temperature can be improved.

2. Description of the Related Art

An image sensor is an element in which, when light is incident on a photo conductive body through a color filter, an electron-hole generated by the photo conductive body according to the wavelength and intensity of the light forms a signal to transmit to an output section. The image sensor is divided into a CCD (charged coupled device) image sensor and CMOS (complementary metal oxide semiconductor) image sensor.

The CCD image sensor is composed of a photo diode which receives light, a charge transmitting section, and a signal output section. The photo diode receives light to generate signal charges, the charge transmitting section uses a CCD to transmit the signal charges generated by the photo diode to the signal output section without loss, and the signal output section accumulates the signal charges and detects a voltage proportional to the amount of signal charge to produce an analog output. Since the signal charges are converted into a voltage in the last step, the CCD image sensor has excellent noise characteristics, and is accordingly used in a digital camera, camcorder, or the like. In the above CCD image sensor, a driving method thereof is so complicated that a large voltage is required, and the power consumption thereof is large because a separate driving circuit is needed. Further, a signal processing circuit cannot be implemented within a CCD chip because the number of mask processes is large. Accordingly, in order to overcome such drawbacks, the development of a submicron CMOS image sensor is being actively performed.

Different from the CCD image sensor, a CMOS image sensor converts signal charges generated by each photo diode into a voltage and transmits the converted voltage to the last step. Therefore, in the CMOS image sensor, the signal thereof is weaker than that of the CCD image sensor, and noise not only occurs regularly but also occurs due to a dark current. However, as a semiconductor processing technology develops, a CDS (correlated double sampling) circuit is adopted to significantly reduce reset noise so that an improved image signal can be obtained. In other words, the CDS circuit samples a reset voltage of an image pixel and then samples a signal voltage. At this time, an output of the CDS circuit equals the difference between the reset voltage and the signal voltage. Thus, the CDS circuit may reduce fixed pattern noises due to threshold voltage differences of the transistors in image pixels as well as the reset noises due to the reset voltage differences, thereby obtaining a higher resolution image. Therefore, the CMOS image sensor is widely used in a digital camera, a mobile phone, a PC camera, and the like. Further, the use of the CMOS image sensor is expanded to an automobile.

On the other hand, in order to implement such an image sensor used in an automobile, it is more important to minimize a dark current and improve operational characteristics at high temperature than to reduce the size of an image pixel.

Further, the CMOS image sensor should satisfy many requirements so as to obtain a high resolution image. That is, the CMOS image sensor should achieve a high S/N ratio, high quantum efficiency, a high fill factor, and a high dynamic range.

In order to meet such requirements which the CMOS image sensor should satisfy, the structure of the image pixel has developed in an order of a one-transistor structure, a three-transistor structure, and a four-transistor structure.

FIG. 1 is a diagram illustrating a conventional CMOS image sensor 1 and peripheral elements thereof. The CMOS image sensor 1 includes a photo diode which is a light receiving section and a plurality of image pixels 100 of which each is composed of a charge transmitting section and signal output section. Further, the CMOS image sensor 1 is connected to a row selection line 101 composed of a row selection signal input terminal and is connected to a read-out circuit 102 which reads a signal generated by the photo diode and reads out a reference voltage after reset. At this time, the read signal is output to the column selection line 103 composed of a column signal output terminal, and the output signal is converted into an electrical signal through an output buffer 104 and analog/digital converter 105.

FIG. 2 shows a circuit diagram illustrating a conventional three-transistor image pixel 200.

As shown in FIG. 2, the three-transistor image pixel 200 includes a first transistor 203 of which a gate is connected to a first node 206, a drain is connected to a power supply terminal VDD, and a source is connected to a second node 207; a second transistor 204 of which a gate receives a row selection signal 209, a drain is connected to the second node 207, and a source is connected to a column selection line 210; a third transistor 202 of which a gate receives a reset signal through a reset signal input terminal, a drain is connected to the power supply terminal VDD, a source is connected to the first node 206; and a photo diode which is connected to the first node 206 and a ground terminal.

The first node 206 serves to store an electric charge generated by the photo diode 201, to generate a voltage corresponding to the stored electric charge, and to discharge the stored electrical charge at the time of the reset operation.

An image sensing operation of the three-transistor image pixel 200 constructed as described above will be described as follows.

In the photo diode 201, electric charges generated by light incident from outside are accumulated. At this time, the accumulated signal charges change the potential of the first node 206 which is the source of the third transistor 202. Such a change in the potential causes the gate potential of the first transistor 203 to be changed, the first transistor 203 serving as a source follower of the image pixel 200.

The change in the gate potential of the first transistor 203 causes the bias of the second node 207 to be changed, the second node being connected to the source of the first transistor 203 or the drain of the second transistor 204.

While the signal charges are accumulated, the potential of the source of the third transistor 202 or the potential of the source of the first transistor 203 is changed. At this time, when the row selection signal 209 is input into the gate of the second transistor 204 through the row selection signal input terminal, a potential difference generated by the signal charges generated by the photo diode 201 is output to the column selection line 210.

After a signal level generated by the charge generation of the photo diode 201 is detected, the third transistor 202 is turned on by the reset signal 208 through the reset signal input terminal. Accordingly, all the signal charges accumulated in the photo diode 201 are reset.

FIG. 3 is a circuit diagram illustrating a conventional four-transistor image pixel 300.

The construction of a four-transistor CMOS image sensor, which is proposed to solve the noise problem of the three-transistor CMOS image sensor, is as follows.

As shown in FIG. 3, the four-transistor image pixel 300 includes a first transistor 303 of which a gate is connected to a first node 306, a drain is connected to a power supply terminal VDD, and a source is connected to a second node 307; a second transistor 304 of which a gate receives a row selection signal 310, a drain is connected to the second node 307, and a source is connected to a column selection line 311; a third transistor 302 of which a gate receives a reset signal 309 through a reset signal input terminal, a drain is connected to the power supply terminal VDD, and a source is connected to the first node 306; a fourth transistor 305 of which a gate receives a transfer signal 312, a drain is connected to the first node 306, and a source is connected to the third node 308; and a photo diode 301 which is connected to the third node 308 and a ground terminal.

As in FIG. 2, the first node shown in FIG. 3 also serves to store an electric charge generated by the photo diode 301, to generate a voltage corresponding to the stored electric charge, and to discharge the stored electric charge at the time of the reset operation.

An image sensing operation of the four-transistor image pixel 300 constructed as described above will be described as follows.

In the photo diode 301, electric charges generated by light incident from outside are accumulated. The accumulated signal charges are focused on the surface of the photo diode 301. At this time, when the transfer signal 312 is input to the gate of the fourth transistor 305 so as to turn on the fourth transistor 305, a signal level is transmitted to the first node 306.

In this state, if the off-state of the third transistor 302 is maintained, the potential of the first node 306 connected to the source of the third transistor 302 is changed y the signal charges accumulated in the first node 306. The change in the potential causes the gate potential of the first transistor 303 to be changed.

The change in the gate potential of the first transistor 303 causes the bias of the second node 307 to be changed, the second node 307 being connected to the source of the first transistor 303 or the drain of the second transistor 304.

While the signal charges are accumulated, the potential of the source of the third transistor 302 or the potential of the source of the first transistor 303 is changed. At this time, when the row selection signal 310 is input to the gate of the second transistor 304 through the row selection signal input terminal, a potential difference generated by the signal charges generated by the photo diode 301 is output to the column selection line 311.

After a signal level generated by the charge generation of the photo diode 301 is detected, the third transistor 302 is turned on by the reset signal 309 through the reset signal input terminal. Accordingly, all the signal charges accumulated in the photo diode 301 are reset.

Although the image sensing is performed through the image pixel 200 or 300 shown in FIG. 2 or 3 so as to output an image signal, a dark current I_{D1} generated by the photo diode 201 or 301 causes noise to be generated in the image signal. Accordingly, a distorted image signal is output.

The dark current is a non-preferable current which is generated by the image pixel of the image sensor even when no light signal is coming, which means a current which is generated within a depletion layer by heat energy. Therefore, the dark current I_{D1} is also generated in the photo diode 201 or 301. The generated dark current I_{D1} is converted into a voltage by the first transistor 203 or 303 and serves as an output signal when no signal is coming. A distorted image signal is output by the signal generated by the dark current I_{D1}.

FIG. 4 is a diagram illustrating the structure of the image sensor 1 of FIG. 1, which compensates for a dark current. The dark current compensation will be described as follows.

As shown in FIG. 4, dark image pixels 400 among image pixels composing the CMOS image sensor 1 are placed in the outer portion of the CMOS image sensor 1, and the value of the dark current generated thereby is calculated and compensated, in order to compensate the dark current described in FIGS. 2 and 3.

In other words, an average of the dark currents generated by the plurality of dark image pixels 400 is calculated to equally compensate the respective image pixels for the average. Then, the dark current can be minimized.

However, in the image pixel of the CMOS image sensor according to the related art, since an average of the dark currents generated by the dark image pixels is calculated to equally compensate the respective image pixels for the average in order to compensate the dark current, individual compensation for each image pixel cannot performed.

Further, in the dark current compensation according to the related art, since the compensation of dark current is not performed for each image pixel, the photo diode of the image pixel is quickly discharged at the time of the operation at high temperature where the dark current increases, so that the characteristics of the image pixel are deteriorated.

### SUMMARY OF THE INVENTION

An advantage of the present invention is that it provides an image sensor of a CMOS image sensor, in which a dark diode serving as a dark current source is directly connected to a photo diode so that a dark current generated in an image pixel can be minimized. Further, since noise which can be generated by the dark current can be reduced, a high S/N ratio is obtained, and dynamic range and low illumination characteristics are enhanced. In addition, since characteristic deterioration at high temperature is prevented, operational characteristics at high temperature can be improved.

Additional aspects and advantages of the present general inventive concept will be set forth in part in the description which follows and, in part, will be obvious from the description, or may be learned by practice of the general inventive concept.

According to an aspect of the invention, an image pixel of a CMOS image sensor includes a photoelectric conversion element that is connected to a first node and ground terminal so as to generate a signal by using incident light; an electric current source that is connected to the first node and a power supply terminal so as to supply a dark current; a first switch that is connected to a second node, the power supply terminal, and the first node and that changes the potential of a node connected to the first node by using the signal charges accumulated in the first node so that the bias of the second node is changed; a second switch that is connected to the first switch and that receives a row selection signal so as to output a potential difference generated by the signal generated by the photoelectric conversion element to a column selection line; and a third switch that is connected between the first node and the power supply terminal and that receives a reset signal so as to reset the signal charges accumulated in the first node.

The photoelectric conversion element is a photo diode, the anode terminal of the photo diode is connected to the ground terminal, and the cathode terminal thereof is connected to the first node.

The electric current source is a dark current, which is covered with metal so that light is not transmitted thereto, the anode terminal of the dark diode is connected to the first node, and the cathode thereof is connected to the power source terminal.

The first switch is a transistor, the gate of the transistor is connected to the first node, the drain thereof is connected to the power supply terminal, and the source thereof is connected to the second node.

The second switch is a transistor, the gate of the transistor receives a row selection signal, the drain thereof is connected to the second node, and the source thereof is connected to the column selection line.

The third switch is a transistor, the gate of the transistor receives a reset signal, the drain thereof is connected to the power supply terminal, and the source thereof is connected to the first node.

According to another aspect of the invention, an image pixel of a CMOS image sensor includes a photoelectric conversion element that is connected to a third node and ground terminal so as to generate a signal by using incident light; an electric current source that is connected to the third node and a power supply terminal so as to supply a dark current; a first switch that is connected to a second node, power supply terminal, and first node and that changes the potential of a node connected to the first node by using the signal charges accumulated in the first node so that the bias of the second node is changed; a second switch that is connected to the first switch and that receives a row selection signal so as to output a potential difference generated by the signal generated by the photoelectric conversion element to a column selection line; a third switch that is connected between the first node and the power supply terminal and that receives a reset signal so as to reset the signal charges accumulated in the first node; and a fourth switch that is connected to the first and third nodes and that receives a transfer signal so as to transfer the signal charges generated by the photoelectric conversion element.

The photoelectric conversion element is a photo diode, the anode terminal of the photo diode is connected to the ground terminal, and the cathode terminal thereof is connected to the third node.

The electric current source is a dark diode, which is covered with metal so that light is not transmitted thereto, the anode terminal of the dark diode is connected to the third node, and the cathode thereof is connected to the power source terminal.

The first switch is a transistor, the gate of the transistor is connected to the first node, the drain thereof is connected to the power supply terminal, and the source thereof is connected to the second node.

The second switch is a transistor, the gate of the transistor receives a row selection signal, the drain thereof is connected to the second node, and the source thereof is connected to the column selection line.

The third switch is a transistor, the gate of the transistor receives a reset signal, the drain thereof is connected to the power supply terminal, and the source thereof is connected to the first node.

The fourth switch is a transistor, the gate of the transistor receives a transfer signal, the drain thereof is connected to the first node, and the source thereof is connected to the third node.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a diagram illustrating a conventional CMOS image sensor and peripheral elements thereof;

FIG. 2 is a circuit diagram illustrating a conventional three-transistor image pixel;

FIG. 3 is a circuit diagram illustrating a conventional four-transistor image pixel according to the related art;

FIG. 4 is a diagram illustrating the structure of the image sensor of FIG. 1 for compensating a dark current;

FIG. 5 is a circuit diagram illustrating an image pixel of a CMOS image sensor according to a first embodiment of the present invention; and

FIG. 6 is a circuit diagram illustrating an image pixel of a CMOS image sensor according to a second embodiment of the present invention.

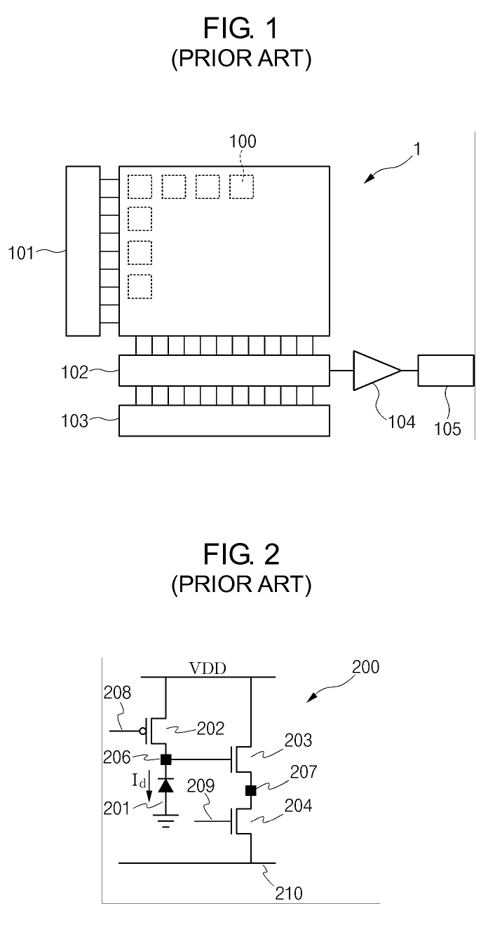

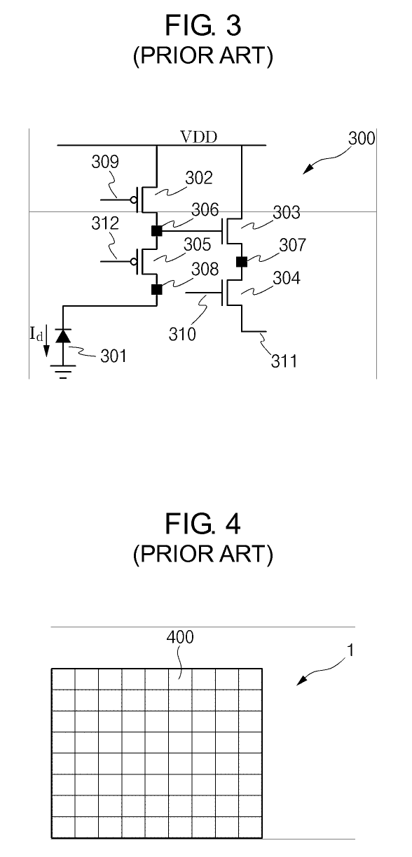

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, preferred embodiments of the present invention will be described in detail with reference to the accompanying drawings.

### First Embodiment

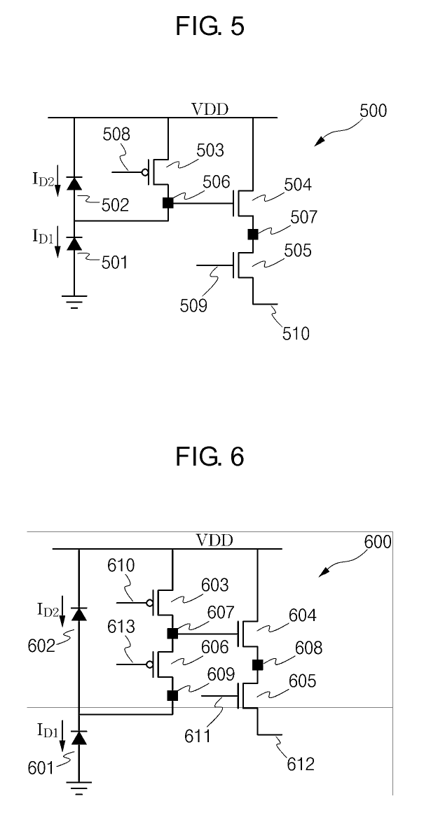

FIG. 5 shows an image pixel 500 of a CMOS image sensor according to a first embodiment of the invention, showing a circuit diagram of the three-transistor image pixel 500.

As shown in FIG. 5, the three-transistor image pixel 500 is composed of a first transistor 504 of which a gate is connected to a first node 506, a drain is connected to a power supply terminal VDD, and a source is connected to a second node 507; a second transistor 505 of which a gate receives a row selection signal 509, a drain is connected to the second node 507, and a source is connected to a column selection line 510; a third transistor 503 of which a gate receives a reset signal 508 through a reset signal input terminal, a drain is connected to the power supply terminal VDD, and a source is connected to the first node 506; a photo diode 501 which is connected to the first node 506 and a ground terminal; and a dark diode 502 which is connected to the first node 506 and the power supply terminal VDD.

The first node 506 serves to store an electric charge generated by the photo diode 501, to generate a voltage corresponding to the stored electric charge, and to discharge the stored electric charge at the time of the reset operation.

In the dark diode 502, on which an opaque material is coated, an electric current generated by light is not present, and only a dark current is generated. Accordingly, the dark diode 502 serves as a dark current source.

An image sensing operation of the three-transistor image pixel 500 constructed as described above and a dark current compensation will be described as follows.

In the photo diode 501, electric charges are accumulated by light incident from outside. At this time, the accumulated signal charges change the potential of the first node 506 which is the source of the third transistor 503, and such a change in the potential causes the gate potential of the first transistor 504 to be changed, the first transistor 504 serving as a source follower of the image pixel 500.

The change in the gate potential of the first transistor 504 causes the bias of the second node 507 to be changed, the second node 507 being connected to the source of the first transistor 504 and the drain of the second transistor 505.

While the signal charges are accumulated, the potential of the source of the third transistor 503 or the potential of the source of the first transistor 504 is changed. At this time, if the row selection signal 509 is input into the gate of the second transistor 505 through the row selection signal input terminal, a potential difference generated by the signal charges generated by the photo diode 501 is output to the column selection line 510.

After a signal level generated by the charge generation of the photo diode 501 is detected, the third transistor 503 is turned on by the reset signal 508 through the reset signal input terminal. Accordingly, all the signal charges accumulated in the photo diode 501 are reset.

Although the image sensing of the three-transistor image pixel 500 is performed through the above-described process so as to output an image signal, a dark current I_{D1} generated in the photo diode 501 causes noise to be generated in the image signal. Accordingly, a distorted image signal is output.

In other words, the dark current I_{D1} is generated in the photo diode 501, and the generated dark current I_{D1} is converted into a voltage by the first transistor 504 so as to serve as an output signal even when no signal is coming. Therefore, a distorted image signal is output due to a signal generated by the dark current I_{D1}.

In order to solve the above-described problem, the dark diode 502 serving as a dark current source is directly connected to the photo diode 501 so as to compensate for a dark current which is generated in the photo diode 501.

Because of the dark current I_{D1} generated in the photo diode 501, the first node 506 cannot maintain a constant voltage corresponding to the stored electric charges. However, the anode terminal of the dark diode 502 is connected to the first node 506 which is directly connected to the cathode terminal of the photo diode 501 so as to compensate the first node 506 for the dark current I_{D2} generated in the dark diode 502. Then, the first node 506 can maintain a constant voltage corresponding to the stored electric charges.

In addition, although the dark current I_{D1} generated in the photo diode 501 increases at the time of the operation at high temperature, the dark current I_{D2} of the dark diode 502 also increases as much to thereby prevent characteristic deterioration from occurring during the operation at high temperature.

### Second Embodiment

FIG. 6 shows an image pixel 600 of a CMOS image sensor according to a second embodiment of the present invention, showing a circuit diagram of a four-transistor image pixel 600.

As shown in FIG. 6, the four-transistor image pixel 600 is composed of a first transistor 604 of which a gate is connected to a first node 607, a drain is connected to a power supply terminal VDD, and a source is connected to a second node 608; a second transistor 605 of which a gate receives a row selection signal 611, a drain is connected to a second node 608, and a source is connected to a column selection line 612; a third transistor 603 of which a gate receives a reset signal 601 through a reset signal input terminal, a drain is connected to the power supply terminal VDD, and a source is connected to the first node 607; a fourth transistor of which a gate receives a transfer signal 613, a drain is connected to a first node 607, and a source is connected to a third node 609; a photo diode 601 which is connected to the third node 609 and a ground terminal; and a dark diode 602 which is connected to the third node 609 and the power supply terminal VDD.

As in the first embodiment, the first node 607 of the second embodiment serves to store an electric charge generated by the photo diode 601, to generate a voltage corresponding to the stored electric charge, and to discharge the stored electric charge at the time of the reset operation.

Even in the dark diode 602 used in the second embodiment, on which an opaque material is coated, an electric current generated by light is not present, and only a dark current is generated. Accordingly, the dark diode 602 also serves as a dark current source.

An image sensing operation of the four-transistor image pixel 600 constructed as described above and a dark current compensation will be described as follows.

In the photo diode 601, electric charges are accumulated by light incident from outside, and the accumulated signal charges are focused on the surface of the photo diode 601. At this time, the transfer signal 613 is input into the gate of the fourth transistor 606, and a signal level is transmitted to the first node 607 when the fourth transistor 606 is turned on.

In this state, if the off-state of the third transistor 603 is maintained, the potential of the first node 607 connected to the source of the third transistor 603 is changed by the signal charges accumulated in the first node 607. Such a change in the potential causes the gate potential of the first transistor 604 to be changed.

The change in the gate potential of the first transistor 604 causes the bias of the second node 608 to be changed, the second node 608 being connected to the source of the first transistor 604 or the drain of the second transistor 605.

While the signal charges are accumulated, the potential of the source of the third transistor 603 or the potential of the source of the first transistor 604 is changed. At this time, if the row selection signal 611 is input into the gate of the second transistor 605 through the row selection signal input terminal, a potential difference generated by the signal charges generated by the photo diode 601 is output to the column selection line 612.

After the signal level generated by the charge generation of the photo diode 601 is detected, the third transistor 603 is turned on by the reset signal 601 through the reset signal input terminal. Accordingly, all the signal charges accumulated in the photo diode 601 are reset.

Although the image sensing of the four-transistor image pixel 600 is performed through the above-described process so as to output an image signal, a dark current I_{D1} generated in the photo diode 601 causes noise to be generated in the image signal. Accordingly, a distorted image signal is output.

In other words, as in the first embodiment, the dark current I_{D1} is generated in the photo diode 601, and the generated dark current I_{D1} is converted into a voltage by the first transistor 604 so as to serve as an output signal even when no signal is coming. Therefore, a distorted image signal is output due to a signal generated by the dark current I_{D1}.

In order to solve the above-described problem, the dark diode 602 serving as a dark current source is directly connected to the photo diode 601 so as to compensate for a dark current which is generated in the photo diode 601.

Because of the dark current I_{D1} generated in the photo diode 601, the third node 609 cannot maintain a constant voltage required for outputting an image. However, the anode terminal of the dark diode 602 is connected to the third node 609 which is directly connected to the cathode node of the photo diode 601 so as to compensate the third node 609 for a dark current I_{D2} generated in the dark diode 602. Accordingly, the third node 609 can maintain a constant voltage required for outputting an image.

As in the first embodiment, although the dark current I_{D1} generated in the photo diode 601 increases at the time of the operation at high temperature, the dark current I_{D2} of the dark diode 602 also increases as much to thereby prevent characteristic deterioration from occurring during the operation at high temperature.

While the present invention has been described with reference to exemplary embodiments thereof, it will be understood by those skilled in the art that various changes and modifications in form and detail may be made therein without departing from the scope of the present invention as defined by the following claims.

As described above, in the image pixel of the CMOS image sensor according to the present invention, the dark diode serving as a dark current source is directly connected to the photo diode so as to compensate for the dark current generated in the photo diode. Therefore, the dark current which is generated in the image pixel can be minimized.

Since minimizing the dark current allows the resultant noise to be reduced, a high S/N ratio is obtained and dynamic range characteristics are enhanced. Further, low illumination characteristics are improved, in which the shape or the like can be detected in a dark place.

Furthermore, as the temperature increases, the dark current generated in the photo diode also increases. However, since the dark current of the dark diode also increases as much, characteristic deterioration at high temperature is prevented so that operational characteristics at high temperature are improved.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An image pixel of a CMOS image sensor comprising:
a photoelectric conversion element that is connected to a first node and ground terminal so as to generate a signal by using incident light;
an electric current source that is connected to the first node and a power supply terminal so as to supply a dark current;
a first switch that is connected to a second node, the power supply terminal, and the first node and that changes the potential of a node connected to the first node by using the signal charges accumulated in the first node so that the bias of the second node is changed;
a second switch that is connected to the first switch and that receives a row selection signal so as to output a potential difference generated by the signal generated by the photoelectric conversion element to a column selection line; and
a third switch that is connected between the first node and the power supply terminal and that receives a reset signal so as to reset the signal charges accumulated in the first node.

2. The image pixel of a CMOS image sensor according to claim 1,
wherein the photoelectric conversion element is a photo diode, the anode terminal of the photo diode is connected to the ground terminal, and the cathode terminal thereof is connected to the first node.

3. The image pixel of a CMOS image sensor according to claim 1,
wherein the electric current source is a dark current, which is covered with metal so that light is not transmitted thereto, the anode terminal of the dark diode is connected to the first node, and the cathode thereof is connected to the power source terminal.

4. The image pixel of a CMOS image sensor according to claim 1,
wherein the first switch is a transistor, the gate of the transistor is connected to the first node, the drain thereof is connected to the power supply terminal, and the source thereof is connected to the second node.

5. The image pixel of a CMOS image sensor according to claim 1,
wherein the second switch is a transistor, the gate of the transistor receives a row selection signal, the drain thereof is connected to the second node, and the source thereof is connected to the column selection line.

6. The image pixel of a CMOS image sensor according to claim 1,
wherein the third switch is a transistor, the gate of the transistor receives a reset signal, the drain thereof is connected to the power supply terminal, and the source thereof is connected to the first node.

7. An image pixel of a CMOS image sensor comprising:
a photoelectric conversion element that is connected to a third node and ground terminal so as to generate a signal by using incident light;
an electric current source that is connected to the third node and a power supply terminal so as to supply a dark current;
a first switch that is connected to a second node, power supply terminal, and first node and that changes the potential of a node connected to the first node by using the signal charges accumulated in the first node so that the bias of the second node is changed;
a second switch that is connected to the first switch and that receives a row selection signal so as to output a potential difference generated by the signal generated by the photoelectric conversion element to a column selection line;
a third switch that is connected between the first node and the power supply terminal and that receives a reset signal so as to reset the signal charges accumulated in the first node; and
a fourth switch that is connected to the first and third nodes and that receives a transfer signal so as to transfer the signal charges generated by the photoelectric conversion element.

8. The image pixel of a CMOS image sensor according to claim 7,
wherein the photoelectric conversion element is a photo diode, the anode terminal of the photo diode is connected to the ground terminal, and the cathode terminal thereof is connected to the third node.

9. The image pixel of a CMOS image sensor according to claim 7,
wherein the electric current source is a dark diode, which is covered with metal so that light is not transmitted thereto, the anode terminal of the dark diode is connected to the third node, and the cathode thereof is connected to the power source terminal.

10. The image pixel of a CMOS image sensor according to claim 7,
wherein the first switch is a transistor, the gate of the transistor is connected to the first node, the drain thereof is connected to the power supply terminal, and the source thereof is connected to the second node.

11. The image pixel of a CMOS image sensor according to claim 7,
wherein the second switch is a transistor, the gate of the transistor receives a row selection signal, the drain thereof is connected to the second node, and the source thereof is connected to the column selection line.

12. The image pixel of a CMOS image sensor according to claim 7,
wherein the third switch is a transistor, the gate of the transistor receives a reset signal, the drain thereof is connected to the power supply terminal, and the source thereof is connected to the first node.

13. The image pixel of a CMOS image sensor according to claim 7,
wherein the fourth switch is a transistor, the gate of the transistor receives a transfer signal, the drain thereof is connected to the first node, and the source thereof is connected to the third node.
